(19) United States
(12) Patent Application Publication
(10) Pub. No.: US 2004/0095195 A1
(43) Pub. Date: May 20, 2004

(54) Adaptive loop bandwidth phase locked loop having deglitch circuit for providing short lock time

(75) Inventors: Hong June Park, Pohang-city (KR); Young Soo Sohn, Seoul (KR)

Correspondence Address: ROTHWELL, FIGG, ERNST & MANBECK, P.C., 1425 K STREET, N.W., SUITE 800, WASHINGTON, DC, 20005, US

(73) Assignee: POSTECH FOUNDATION, Pohang-city (KR)

(21) Appl. No.: 10/701,421

(22) Filed: Nov. 6, 2003

(30) Foreign Application Priority Data
Nov. 6, 2002 (KR) 2002-68363

(51) Int. Cl. H03L 7/00

(52) U.S. Cl. 331/16

(57) ABSTRACT

Provided is an adaptive loop bandwidth phase locked loop (PLL) including a deglitch circuit for providing short lock time. The adaptive loop bandwidth can perform a lock operation without having any bad influence on other devices and can detect a difference between the frequency and phase of a signal using a deglitch circuit in an adaptive loop bandwidth manner that can provide short lock time. The adaptive loop bandwidth PLL includes a first charge pump which receives an up signal and a down signal from the phase frequency comparator; an up signal deglitch circuit and a down signal deglitch circuit which receive the up signal and the down signal, respectively, from the phase frequency comparator and output signals, respectively, indicating a difference between frequency and phase of the predetermined input clock signal; a second charge pump which receives the signals respectively output from the up signal deglitch circuit and the down signal deglitch circuit and has an output port connected to an output port of the first charge pump; and a loop filter which is placed between the voltage-controlled oscillator and the first and second charge pumps, the loop filter filtering out unnecessary components from the signals respectively output from the up signal deglitch circuit and the down signal deglitch circuit and stabilizing the adaptive loop bandwidth PLL.

### BACKGROUND OF THE INVENTION

This application claims the priority of Korean Patent Application No. 2002-68363, filed on Nov. 6, 2002, in the Korean Intellectual Property Office, the disclosure of which is incorporated herein in its entirety by reference.

1. Field of the Invention

The present invention relates to a phase locked loop (PLL), and more particularly, to an adaptive loop bandwidth PLL having a deglitch circuit for providing short lock time, which can perform a lock operation without having any bad influence on other devices and can detect a difference between the frequency and phase of an input clock signal using an adaptive loop bandwidth technique that can provide short lock time.

2. Description of the Related Art

FIG. 1 is a schematic block diagram of a conventional phase locked loop (PLL). Referring to FIG. 1, a PLL detects a phase difference between an input signal (or input clock signal) and an oscillation signal output from a voltage-controlled oscillator (VCO) 8 and thus determines the frequency and phase of the VCO 8. Therefore, it is possible to manufacture an oscillation circuit that can stably oscillate arbitrary frequencies by using the PLL. In FIG. 1, reference numerals 2, 4, 6, and 8 represent a phase frequency comparator, a charge pump, a loop filter, and a voltage-controlled oscillator, respectively.

The PLL can be used as a clock controller mounted on a CMOS chip. In general, the PLL can be used as a zero delay buffer capable of getting rid of time skews of an input signal caused by a buffer, a frequency generator for generating frequency higher than input frequency, or a multi-phase clock generator for generating multi-phase clock signals.

When it comes to a PLL, lock time as well as time jitter is a very important factor to determine the general performance of the PLL. Long lock time means that the PLL is supposed to wait for a long time until a chip operates normally after being turned on. In addition, long lock time also means that it takes a long time for the PLL to return to a normal operation state after a power standby state. The power standby state has been widely adopted by a variety of types of chips recently. Accordingly, long lock time may considerably affect the operation speed of an entire system.

In general, lock time is inversely proportional to loop bandwidth. In other words, the larger loop bandwidth a PLL has, the longer lock time it provides, and the smaller loop bandwidth it has, the shorter lock time it provides. The PLL samples phase variations of an input clock signal. In order to make such digital sampling of the PLL look like a continuous operation, the PLL's loop bandwidth should be smaller than one tenth of input frequency. If the PLL's loop bandwidth is larger than one tenth of the input frequency, the PLL operates unstably. In addition, if the input clock signal has large time jitter, the loop bandwidth of the PLL can be reduced to filter out such noise, which results in longer lock time.

In order to solve the above problems, a variety of techniques for making loop bandwidth normal by increasing the amount of current pumped into the PLL if there is a huge difference between the frequency and phase of the input clock signal and, otherwise, reducing the amount of pumping current have been suggested. Of those conventional techniques, there are a method of analog-measuring phase errors by providing a loop designated for controlling pumping current and a method of digital-measuring the amount of phase error using three phase frequency comparators.

In the method of analog-measuring phase errors by providing a loop designated for controlling pumping current, many factors need to be considered before designing the loop for controlling pumping current. In other words, the current of a resistor and an electric condenser in the loop should be determined, and the current of the resistor and the electric condenser varies depending on the size of overlap between up and down signals output from a phase frequency comparator. Therefore, the loop should be designed in consideration of the variation of the current of the resistor and the electric condenser, which is very complicated.

In the method of digital-measuring the amount of phase error using three phase frequency comparators, unlike in the method of analog-measuring phase errors by providing a loop designated for controlling pumping current, adaptive loop bandwidth can be relatively easily adjusted. However, this method needs three phase frequency comparators, which results in the increase of hardware overhead.

In short, conventional adaptive loop bandwidth PLLs have the following problems. First, in the prior art, a predetermined device for detecting a difference between the frequency and phase of an input clock signal may be necessary in which case many factors, such as the current of the resistor and the electric condenser and a minimum width of overlap between the up and down signals output from the phase frequency comparator, need to be considered before designing an adaptive loop bandwidth PLL including the predetermined device.

Second, in the prior art, three phase frequency comparators are necessary in order to digital-measure a difference between the frequency and phase of the input clock signal, in which case hardware overhead increases.

### SUMMARY OF THE INVENTION

The present invention provides an adaptive loop bandwidth PLL having a deglitch circuit for providing short lock time. The adaptive loop bandwidth PLL can perform a lock operation without having any bad influence on other devices and can detect a difference between the frequency and phase of a signal using a deglitch circuit in an adaptive loop bandwidth manner that can provide short lock time. Since not many factors need to be considered in the design of the adaptive loop bandwidth PLL is easy to design and realize, it is easy to realize the adaptive loop bandwidth PLL. In addition, the adaptive loop bandwidth PLL has less hardware overhead.

According to an aspect of the present invention, there is provided an adaptive loop bandwidth phase locked loop (PLL), including a phase frequency comparator that receives a predetermined input clock signal and a voltage controlled oscillator. The adaptive loop bandwidth PLL includes a first charge pump which receives an up signal and a down signal from the phase frequency comparator; an up signal deglitch circuit and a down signal deglitch circuit which receive the up signal and the down signal, respectively, from the phase frequency comparator and output signals, respectively, indicating a difference between frequency and phase of the predetermined input clock signal; a second charge pump which receives the signals respectively output from the up signal deglitch circuit and the down signal deglitch circuit and has an output port connected to an output port of the first charge pump; and a loop filter which is placed between the voltage-controlled oscillator and the first and second charge pumps, the loop filter filtering out unnecessary components from the signals respectively output from the up signal deglitch circuit and the down signal deglitch circuit and stabilizing the adaptive loop bandwidth PLL.

Preferably, the second charge pump is driven by the signals respectively output from the up signal deglitch signal and the down signal deglitch signal.

Preferably, the loop filter is driven by the first and second charge pumps.

Preferably, the voltage-controlled oscillator is driven by a signal output from the loop filter, and a signal output from the voltage-controlled oscillator is applied to the phase frequency comparator.

According to another aspect of the present invention, there is provided an adaptive loop bandwidth PLL, including a phase frequency comparator that receives a predetermined input clock signal and a voltage controlled oscillator. The adaptive loop bandwidth PLL includes a first charge pump which receives an up signal and a down signal from the phase frequency comparator; a second charge pump which receives the up signal and the down signal from the phase frequency comparator and has a predetermined enable port; a logic OR gate which receives the up signal and the down signal from the phase frequency comparator; a deglitch circuit which receives a signal output from the logic OR gate and applies the received signal to the enable port of the second charge pump; and a loop filter which is placed between the voltage-controlled oscillator and the charge pump, the loop filter filtering out unnecessary components from signals respectively output from each of the first and second charge pumps and stabilizing the adaptive loop bandwidth PLL.

Preferably, the second charge pump is driven when a signal output from the deglitch circuit is applied to the enable port.

Preferably, the loop filter is driven by the first and second charge pumps.

Preferably, the voltage-controlled oscillator is driven by a signal output from the loop filter, and a signal output from the voltage-controlled oscillator is applied to the phase frequency comparator.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of a conventional phase locked loop (PLL);

FIG. 2 is a block diagram of an adaptive loop bandwidth PLL according to a preferred embodiment of the present invention;

FIG. 3 is a block diagram of an adaptive loop bandwidth PLL according to another preferred embodiment of the present invention;

FIG. 4 is a graph showing loop gains with respect to loop bandwidth according to a preferred embodiment of the present invention;

FIG. 5 is a timing diagram illustrating the operation of a deglitch circuit according to a preferred embodiment of the present invention;

FIG. 6 is a block diagram of a deglitch circuit according to a preferred embodiment of the present invention; and

FIGS. 7A and 7B are graphs comparing an output signal of a loop filter of an adaptive loop bandwidth PLL according to a preferred embodiment of the present invention with an output signal of a loop filter of a conventional PLL.

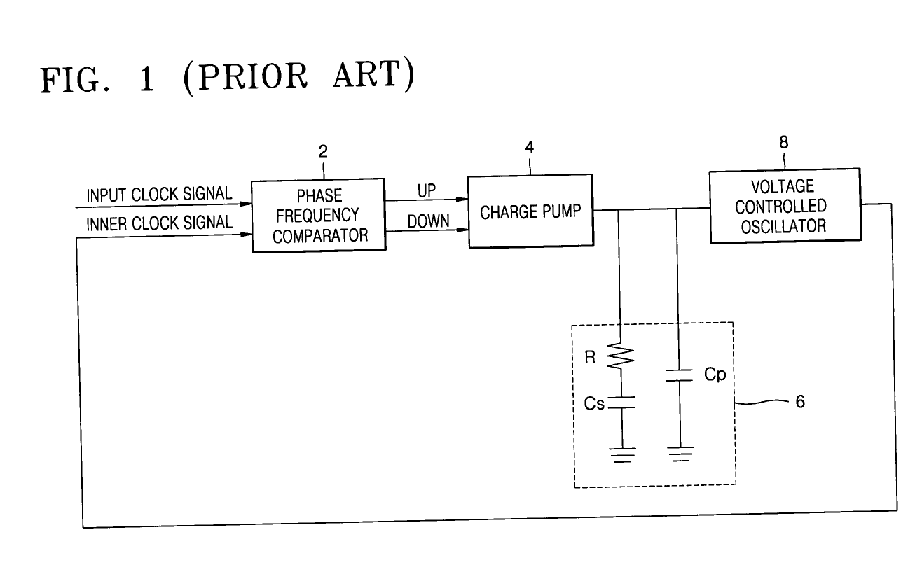

### DETAILED DESCRIPTION OF THE INVENTION

Hereinafter, the present invention will be described more fully with reference to the accompanying drawings in which preferred embodiments of the invention are shown. In this disclosure, detailed description of conventional techniques and conventional structures, which are considered related to the present invention, may not be presented if it is determined as making the concept or scope of the present invention unclear unnecessarily. In addition, all terms mentioned throughout this disclosure are the ones generally defined based on the functions of what they represent in the present invention, and thus their definitions may vary depending on users' intent or custom. Therefore, those terms should be defined based on the content of the present invention presented here in this disclosure. The same reference numerals in different drawings represent the same elements, and thus their description will not be repeated.

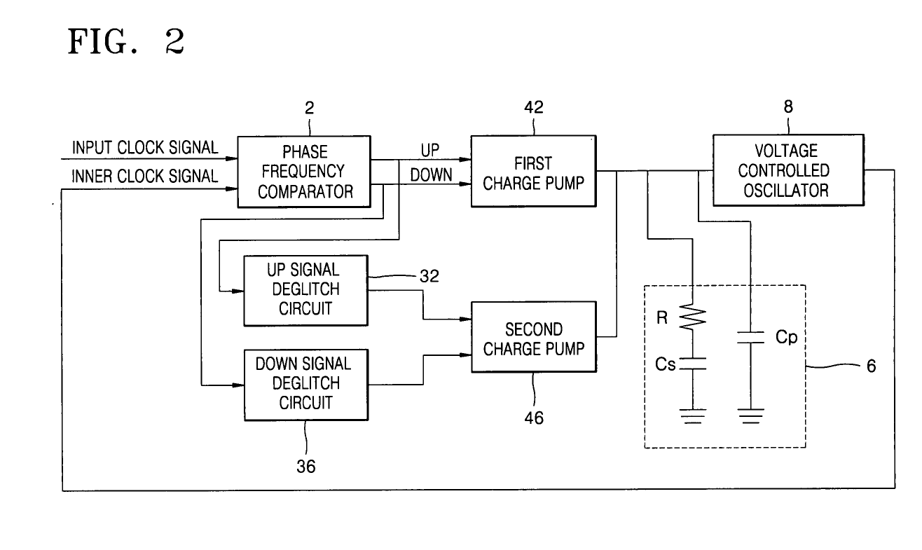

Referring to FIG. 2, an adaptive loop bandwidth phase locked loop (PLL) according to a preferred embodiment of the present invention includes a phase frequency comparator 2 which receives a predetermined input clock signal (or an input signal) and a voltage-controlled oscillator 8. The adaptive loop bandwidth PLL further includes a first charge pump 42 which directly receives an up signal and a down signal from the phase frequency comparator 2, an up signal deglitch circuit 32 which receives the up signal from the phase frequency comparator 2 and outputs a signal up_bst used for detecting a difference between the frequency and phase of the up signal, a down signal deglitch circuit 36 which receives the down signal from the phase frequency comparator 2 and outputs a signal down_bst used for detecting a difference between the frequency and phase of the down signal, a second charge pump 46 which receives the signals up_bst and down_bst from the up and down signal deglitch circuits 32 and 36, respectively, and has an output port connected to an output port of a first charge pump 42, and a loop filter 6 which is interpolated between the voltage-controlled oscillator 8 and the first and second charge pumps 42 and 46 and makes a stable loop by filtering unnecessary signals out from among signals output from the first and second charge pumps 42 and 46. Here, the second charge pump 46 is driven by the output signals up_bst and down_bst of the up and down signal deglitch circuits 32 and 36, the first and second charge pumps 42 and 46 drive the loop filter 6, a signal output from the loop filter 6 drives the voltage-controlled oscillator 8, and a signal output from the voltage-controlled oscillator 8 is applied to the phase frequency comparator 2.

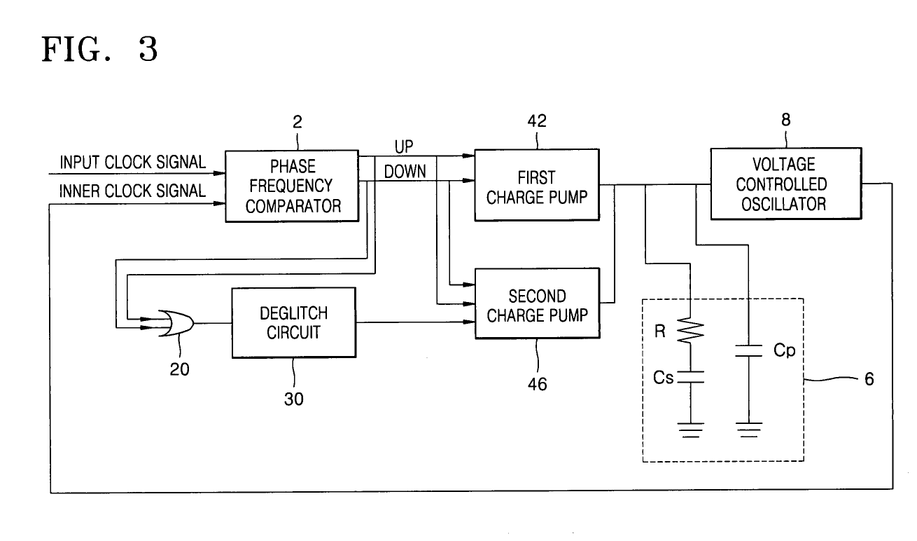

FIG. 3 illustrates an adaptive loop bandwidth PPL according to another preferred embodiment of the present invention. Referring to FIG. 3, the adaptive loop bandwidth PPL includes a phase frequency comparator 2 and a voltage-controlled oscillator 8. In addition, the adaptive loop bandwidth PPL further includes a first charge pump 42 which receives an up signal and a down signal from the phase frequency comparator 2, a second charge pump 46 which also receives the up and down signals from the phase frequency comparator 2 and has a predetermined enable port, a logic OR gate 20 which also receives the up and down signals from the phase frequency comparator 2, a deglitch circuit which receives a signal output from the logic OR gate 20 and applies the received signal to the enable port of the second charge pump 46, and a loop filter 6 which is interpolated between the voltage-controlled oscillator 8 and the first and second charge pumps 42 and 46 and makes a stable loop by filtering unnecessary signals out from among signals output from the first and second charge pumps 42 and 46.

The operation of the adaptive loop bandwidth PPL according to the present invention will be described more fully with reference to FIGS. 2 through 7 in the following paragraphs.

As shown in FIG. 2, an input clock signal is input into the adaptive loop bandwidth PLL and then is converted into a phase difference in the phase frequency comparator 2. The up and down signals obtained as results of the conversion are applied to the first charge pump 42. In addition, the up and down signals are applied to the up signal deglitch circuit 32 and the down signal deglitch circuit 36, respectively. The output signals up_bst and down_bst of the up signal and down signal deglitch circuits 32 and 36, respectively, are applied to the second charge pump 46. Here, the first charge pump 42 preferably serves as a typical charge pump, and the second charge pump 46 preferably serves as a complementary charge pump.

The output of the first and second charge pumps 42 and 46 is applied to the loop filter 6. The output of the loop filter 6 is applied to the voltage-controlled oscillator 8 and is output as a predetermined frequency. The predetermined frequency output from the voltage-controlled oscillator 8 is applied to the phase frequency comparator 2, a process which is a negative feedback. Therefore, the adaptive loop bandwidth PLL of the present invention can output the same frequency as an input frequency using the voltage-controlled oscillator 8.

In order to achieve short lock time using the adaptive loop bandwidth PLL of the present invention, loop bandwidth should be enlarged. Loop bandwidth w can be defined by the following equation:

$$w = \frac{{K}_{VCO} {I}_{P} R}{2 π} .$$

In this equation, K_{VCO}, I_{P}, and R represent frequency gain, the amount of current pumped by the first and second charge pumps 42 and 46, and resistance of the loop filter 6, respectively. Therefore, as I_{P} increases, loop bandwidth w becomes larger, which means shorter lock time. However, a maximum loop bandwidth is limited to one tenth of an input frequency, and thus there is a clear limit in increasing I_{P}.

Once loop bandwidth is set to a predetermined value, frequency compensation is carried out by placing the predetermined value between ‘zero’ and ‘pole’, thus stabilizing the adaptive loop bandwidth PLL. This process is what the loop filter 6 is used for. As described above, lock time is dependent on loop bandwidth. Therefore, when I_{P} is kept increasing after loop bandwidth is set to the predetermined value, the loop may fall into an unstable state having a decreasing phase margin.

FIG. 4 shows open loop gain variations along the axis of frequency. In FIG. 4, a thick line represents open loop gain variations of a PLL that normally operates. As shown in FIG. 4, loop bandwidth w₀ is placed between the ‘zero and ‘pole’ of the loop filter 6, and a maximum phase margin is obtained with the loop bandwidth w₀. Under this condition, if I_{P} is kept increasing, the loop falls into an unstable state having a decreasing phase margin. Therefore, it is necessary to appropriately control I_{P}. More specifically, if there is a huge difference between the frequency and phase of the input clock signal, the second charge pump 46 as well as the first charge pump 42 is used to increase I_{P}. On the other hand, if there is only a small difference between the frequency and phase of the input clock signal, I_{P} is decreased by turning off the second charge pump 46, thus making the PLL normally operate. This method is an adaptive loop bandwidth method according to a preferred embodiment of the present invention.

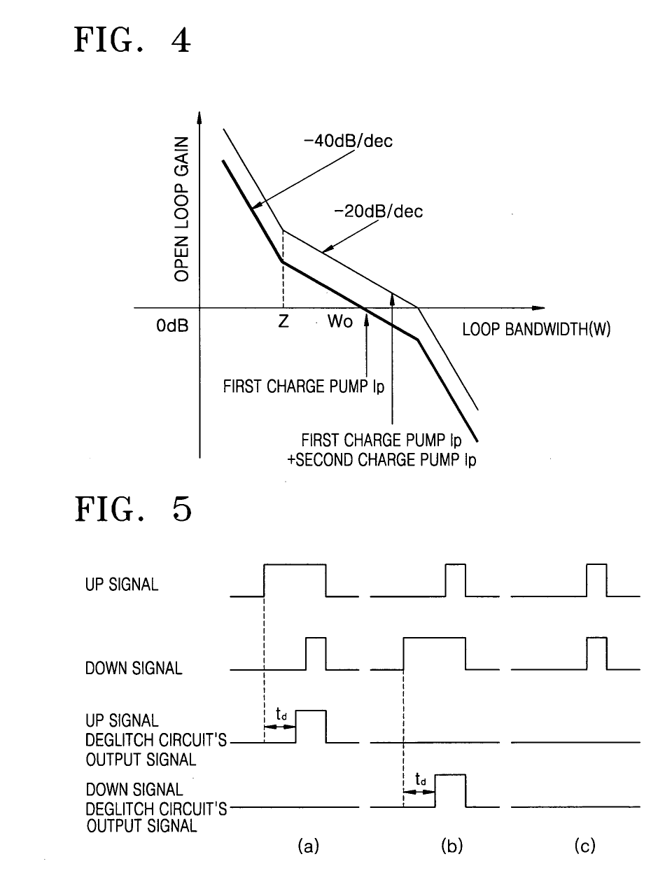

In order to detect a frequency-phase difference, the deglitch circuits 32 and 36 are used in the present invention. If a duty of an original input clock signal is not larger than a predetermined value, the deglitch circuits 32 and 36 determine the input clock signal as a glitch and prevent the input clock signal from affecting their outputs. On the other hand, if the duty of the original input clock signal is not smaller than the predetermined value, the deglitch circuits 32 and 36 pass the input clock signal. After receiving the up and down signals output from the phase frequency comparator 2, the deglitch circuits 32 and 36 assume that there is a huge difference between the frequency and phase of the input clock signal if a ‘high’ period of each of the up and down signals lasts longer than a predetermined period of time t_{d}, as shown in (a) and (b) of FIG. 5. Thereafter, the deglitch circuits 32 and 36 turn on the second charge pump 46, which is a complementary charge pump. Accordingly, I_{P} and the loop bandwidth w increase, and lock time decreases. If the ‘high’ period of each of the up and down signals is shorter than the predetermined period of time t_{d}, as shown in (c) of FIG. 5, the deglitch circuits 32 and 36 assume that there is a small difference between the frequency and phase of the input clock signal and then turns off the second charge pump 46. Accordingly, I_{P} and the loop bandwidth w decrease. Therefore, it is possible to make the PLL stably operate and have a maximum phase margin by appropriately adjusting I_{P}, i.e., by setting I_{P} to a predetermined value between the ‘zero’ and ‘pole’ of the loop filter 6. Preferably, the predetermined period of time (t_{d}) used for determining the input clock signal as a glitch is set to 20% of the period of the input clock signal, and when the second charge pump 46 is turned on, I_{P} is increased not to the extent that the loop bandwidth w exceeds a third pole p₃ of FIG. 4.

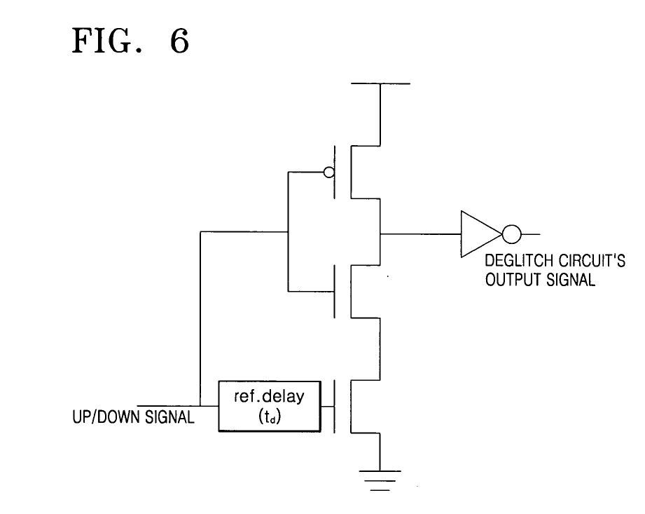

The deglitch circuits 32 and 36 in the PLL of the present invention may have various structures. FIG. 6 illustrates one example of the deglitch circuits 32 and 36. Referring to FIG. 6, if the up or down signal is in a low state, then a Q node is charged to a high state, and a deglitch circuit outputs a low-state signal. If the high state of the up or down signal lasts longer than the predetermined period of time t_{d}, the Q node is discharged, and the deglitch circuit outputs a high-state signal. If the high state of the up or down signal lasts shorter than the predetermined period of time t_{d}, the Q node is not discharged, and thus the output signal of the deglitch signal maintains a low state.

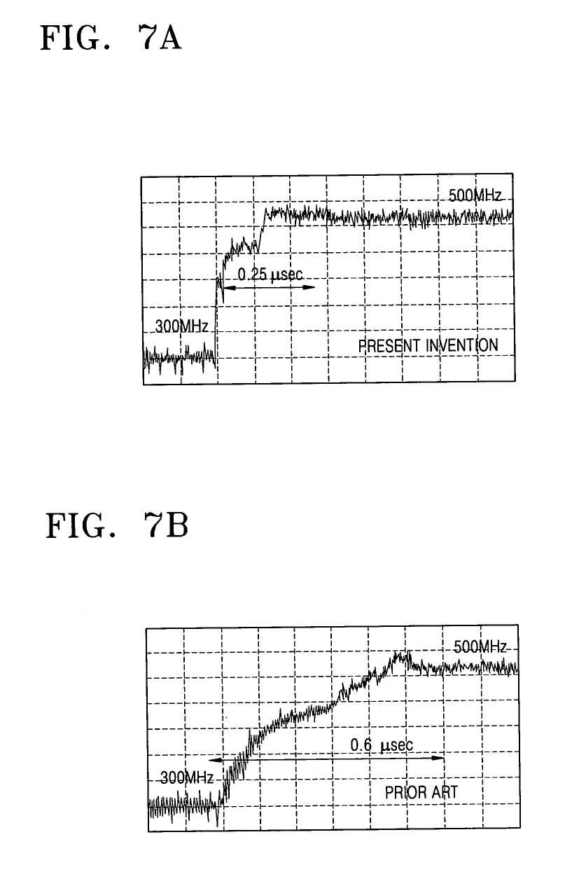

FIGS. 7A and 7B are graphs for comparing the output signal of a loop filter of an adaptive loop bandwidth PLL according to a preferred embodiment of the present invention with the output signal of a loop filter of a conventional PLL. Referring to FIGS. 7A and 7B, the adaptive loop bandwidth PLL of the present invention provides 2.5 times shorter lock time than the conventional PLL.

In addition, as shown in FIGS. 7A and 7B, the adaptive loop bandwidth PLL of the present invention has almost the same time jitter characteristic as its conventional counterpart has. Therefore, in lock state, the adaptive loop bandwidth PLL of the present invention operates having the same loop bandwidth as the conventional PLL has.

FIG. 3 is a block diagram of an adaptive loop bandwidth PLL according to another preferred embodiment of the present invention. The adaptive loop bandwidth PLL of FIG. 3 has the same structure as that of the adaptive loop bandwidth PLL of FIG. 3 except that up and down signals output from a phase frequency comparator 2 are applied to a deglitch circuit 30 passing through a logic OR gate 20. In the adaptive loop bandwidth PLL of FIG. 3, the output of the deglitch circuit 30 is used as an enable signal that enables a second charge pump 46, which is a complementary charge pump. Therefore, the second charge pump 46 is allowed to operate only when there is a huge difference between the frequency and phase of an input clock signal. Thus, it is safe to say that the adaptive loop bandwidth PLL of FIG. 3 provides the same effects and advantages as the adaptive loop bandwidth PLL of FIG. 2 does.

As described above, the adaptive loop bandwidth PLL of the present invention can perform a lock operation without having any bad influence on other devices and can detect a difference between the frequency and phase of a signal using a deglitch circuit in an adaptive loop bandwidth manner that can provide short lock time. Therefore, the adaptive loop bandwidth PLL of the present invention is easy to design with fewer things considered. In addition, the adaptive loop bandwidth PLL of the present invention has smaller hardware overhead.

More specifically, the adaptive loop bandwidth PLL of the present invention has the following advantages. First, the adaptive loop bandwidth PLL of the present invention has the same loop characteristics in lock state as in non-lock state and provides shorter lock time. Second, the adaptive loop bandwidth PLL of the present invention is easier than a conventional PLL to design because it has a simpler hardware structure than its conventional counterpart's.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An adaptive loop bandwidth phase locked loop (PLL), including a phase frequency comparator that receives a predetermined input clock signal and a voltage controlled oscillator, the adaptive loop bandwidth PLL comprising:
a first charge pump which receives an up signal and a down signal from the phase frequency comparator;
an up signal deglitch circuit and a down signal deglitch circuit which receive the up signal and the down signal, respectively, from the phase frequency comparator and output signals, respectively, indicating a difference between frequency and phase of the predetermined input clock signal;
a second charge pump which receives the signals respectively output from the up signal deglitch circuit and the down signal deglitch circuit and has an output port connected to an output port of the first charge pump; and
a loop filter which is placed between the voltage-controlled oscillator and the first and second charge pumps, the loop filter filtering out unnecessary components from the signals respectively output from the up signal deglitch circuit and the down signal deglitch circuit and stabilizing the adaptive loop bandwidth PLL.

2. The adaptive loop bandwidth PLL of claim 1, wherein the second charge pump is driven by the signals respectively output from the up signal deglitch signal and the down signal deglitch signal.

3. The adaptive loop bandwidth PLL of claim 1, wherein the loop filter is driven by the first and second charge pumps.

4. The adaptive loop bandwidth of any of claims 1 through 3, the voltage-controlled oscillator is driven by a signal output from the loop filter, and a signal output from the voltage-controlled oscillator is applied to the phase frequency comparator.

5. An adaptive loop bandwidth PLL, including a phase frequency comparator that receives a predetermined input clock signal and a voltage controlled oscillator, the adaptive loop bandwidth PLL comprising:
a first charge pump which receives an up signal and a down signal from the phase frequency comparator;
a second charge pump which receives the up signal and the down signal from the phase frequency comparator and has a predetermined enable port;
a logic OR gate which receives the up signal and the down signal from the phase frequency comparator;
a deglitch circuit which receives a signal output from the logic OR gate and applies the received signal to the enable port of the second charge pump; and
a loop filter which is placed between the voltage-controlled oscillator and the charge pump, the loop filter filtering out unnecessary components from signals respectively output from each of the first and second charge pumps and stabilizing the adaptive loop bandwidth PLL.

6. The adaptive loop bandwidth PLL of claim 5, wherein the second charge pump is driven when a signal output from the deglitch circuit is applied to the enable port.

7. The adaptive loop bandwidth PLL of claim 5, wherein the loop filter is driven by the first and second charge pumps.

8. The adaptive loop bandwidth of any of claims 5 through 7, the voltage-controlled oscillator is driven by a signal output from the loop filter, and a signal output from the voltage-controlled oscillator is applied to the phase frequency comparator.
